(19) United States
(12) Patent Application Publication
(10) Pub. No.: US 2008/0052018 A1
(43) Pub. Date: Feb. 28, 2008

(54) POWER SOURCE TESTER

(75) Inventors: Mark Petersen, North Vancouver (CA); Gerard F. McLean, West Vancouver (CA); Gagandeep Dhillon, Surrey (CA); Duhane Lam, Vancouver (CA)

Correspondence Address: SCHWEGMAN, LUNDBERG & WOESSNER, P.A., P.O. BOX 2938, MINNEAPOLIS, MN, 55402, US

(73) Assignee: Angstrom Power Inc.

(21) Appl. No.: 11/832,283

(22) Filed: Aug. 1, 2007

Related U.S. Application Data
(60) Provisional application No. 60/821,093, filed on Aug. 1, 2006.

(51) Int. Cl. G01R 21/00

(52) U.S. Cl. 702/62; 702/60; 702/61

(57) ABSTRACT

A power source tester includes a processor and an internal variable load controlled by the processor. A network communication port is coupled to the processor. A pair of inputs is also coupled to the processor for coupling to a power source to be tested under control of the processor. In a method executed by the tester, remote commands are received via a network interface to select one or more tests to be run by the tester. The selected tests are started and data is collected and logged. The data is then sent via the network interface to a remote computer.

### BACKGROUND

Tester for batteries and other power sources, such as fuel cells can range from very simple and inexpensive, to more complex multiple function testers that can run multiple different kinds of tests. For many applications, the simple testers, such as those that measure voltage or current, do not provide a robust test, or do not collect sufficient data that can be later analyzed. The more complex multiple function testers provide much better functionality, but are very expensive, running in to the tens of thousands of dollars (US).

A fuel cell is a device that converts a fuel such as hydrogen or methanol into electricity through an electrochemical reaction. Fuel cells are currently being developed for a wide variety of applications, from fuel cells for automotive and stationary power to micro fuel cells for battery replacement in portable electronic devices. Current test stations are large, complex, and expensive.

### BRIEF DESCRIPTION OF THE DRAWINGS

FIG. 1 shows an embodiment of a power source tester according to an example embodiment.

FIG. 2 shows an embodiment of a power source tester with an external load according to an example embodiment.

FIG. 3 is a schematic diagram of a power source tester according to an example embodiment.

FIG. 4 is a rear view of the power source tester according to an example embodiment.

FIG. 5 is a software flow diagram for an embodiment of a power source tester according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

In this document, the terms “a” or “an” are used to include one or more than one and the term “or” is used to refer to a nonexclusive “or” unless otherwise indicated. In addition, it is to be understood that the phraseology or terminology employed herein, and not otherwise defined, is for the purpose of description only and not of limitation. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference should be considered supplementary to that of this document; for irreconcilable inconsistencies, the usage in this document controls.

The functions or algorithms described herein are implemented in software or a combination of software and human implemented procedures in one embodiment. The software may consist of computer executable instructions stored on computer readable media such as memory or other type of storage devices. The term “computer readable media” is also used to represent any means by which the computer readable instructions may be received by the computer, such as by different forms of wireless transmissions. Further, such functions correspond to modules, which are software, hardware, firmware or any combination thereof. Multiple functions are performed in one or more modules as desired, and the embodiments described are merely examples. The software is executed on a digital signal processor, ASIC (Application Specific Integrated Circuit), microprocessor, or other type of processor operating on a computer system, such as a personal computer, server or other computer system.

A power source tester is described in the following paragraphs. The tester may be used for many different types of power sources, such as fuel cells and batteries. Operation of the tester is described, including different tests that may be run, logging of data, and networked communications for downloading data for analysis. Further, the tester may be operated and/or data acquired via a web based interface.

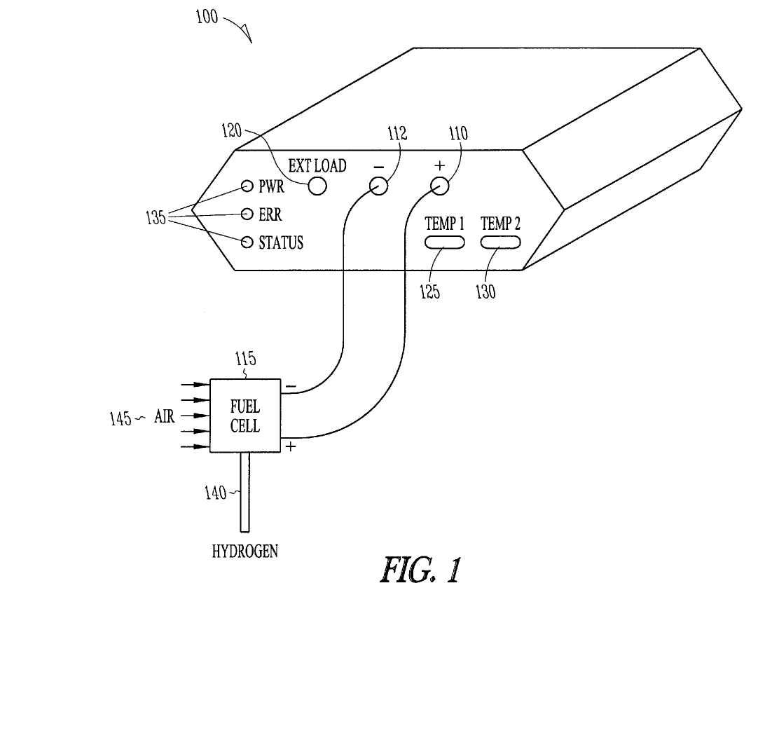

FIG. 1 shows an embodiment of a power source tester 100 according to the current invention. In one embodiment, the power source tester 100 is a fuel cell tester. A front side 105 of the power source tester 100 has a positive 110 and a negative 112 connection for a power source, such as fuel cell 115, a connection 120 for an external load, a first connection 125 for measuring temperature, a second connection 130 for receiving an electrical signal from a transducer, and indicator LEDs (Light Emitting Diode) 135 to indicate power, error, and status conditions. Fuel cell 115 is shown connected to the positive and negative terminals 110, 112 of the tester 100. Other types of power sources, such as batteries and other devices, could also be connected to the positive and negative connections.

In this embodiment, the fuel cell 115 shown is a hydrogen proton exchange membrane (PEM) fuel cell that converts hydrogen gas 140 and oxygen from air 145 into electricity. Different fuel cell types such as direct methanol fuel cells (DMFC), solid oxide fuel cells, and alkaline fuel cells can also be used. Fuel cells running on different fuels such as methanol, formic acid, borohydride compounds (including sodium borohydride and potassium borohydride), butane, etc. can also be used. The “PWR” LED indicates when the tester is being powered. The “ERR” LED indicates when an error condition exists. The “STATUS” LED provides user feedback regarding the status of the fuel cell tester.

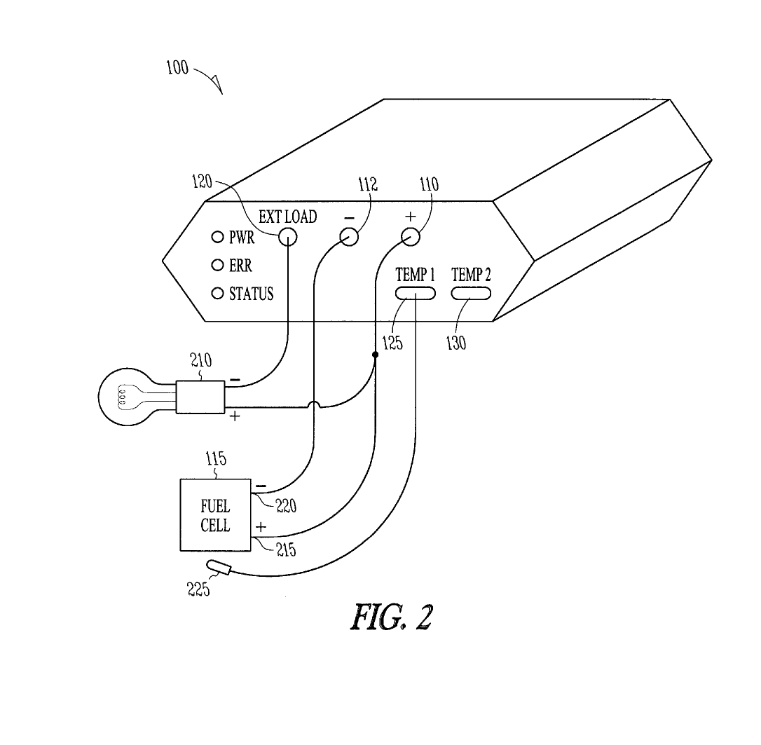

FIG. 2 illustrates an embodiment of tester 100 with an external load 210 connected. A positive side 215 of the fuel cell 115 and the load 210 are connected to the positive terminal 110 on the tester 100. Negative terminal 112 is connected to the fuel cell at 220 and the negative of the load 210 is connected to the “EXT LOAD” external load connection 120. A light source is shown as the load 210, but any other type of load can be used. In this arrangement, a load in the tester may be bypassed and the external load is used as a load to test the power source. In this external load only mode of operation, the tester 100 can measure both voltage and current. The external load connection 120 can be useful in testing a complete fuel cell system where the load is inherent to the device, such as a fuel cell powered flashlight, cellular phone, satellite phone, digital camera, PDA, ultra mobile personal computer (UMPC), laptop computer, computer accessory, personal audio or video player, or combinations thereof, or any device conventionally used with batteries, or any portable electronic device. When testing such a system, it is useful to be able to test the fuel cell with the actual load that will be applied in real use. FIG. 2 also illustrates a thermocouple 225 connected to the “TEMP 1” connection 125. The thermocouple 225 is positioned proximate the fuel cell 115 to measure the temperature of the fuel cell. The temperature of the fuel cell may be related to the power generated by the electrochemical reaction within the fuel cell. In one embodiment, the two connections 125 and 130 are for k-type thermocouples used for measuring temperature. Connection 130 may be used to measure ambient temperature to obtain a difference in temperature between the fuel cell and ambient to better gage the reaction in the fuel cell 115. Examples of suitable thermocouples are available from Omega Engineering, Inc. of Stamford, Conn., USA. Different types of temperature sensors may be used in various embodiments that are capable of providing either analog or digital representations of sensed temperature. In further embodiments, wireless communications between the temperature sensors and the tester 100 may be used.

In further embodiments, one or both of connections 125 and 130 may be used to receive an electrical signal from any type of transducer. In addition to temperature, such transducer may be used to sense gas flow rate, humidity, pressure, radiation, light or other phenomena or combinations thereof.

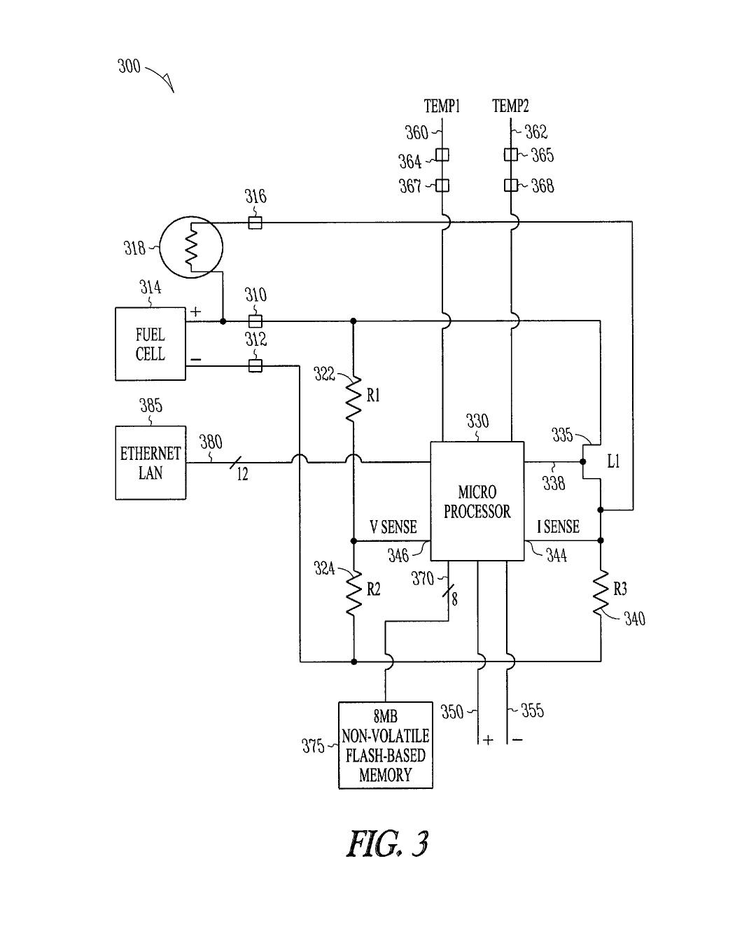

FIG. 3 is an electrical schematic diagram of an example tester 300. Positive 310 and negative 312 connections to fuel cell or power source 314 being tested are shown, as well as the connections 310 and 316 to an external load 318. A voltage divider formed by resistors R1 at 322 and R2 at 324 feed a voltage signal into a microprocessor 330 within an appropriate range. The microprocessor 330 controls a FET-based load L1 335 by sending it a voltage signal on a line 338. The load L1 335 modulates the load in response to the voltage signal by adjusting its resistance.

Alternatively, another type of load can be used that shuts on and off to modulate (e.g., pulse width modulation). When an external load 318 is connected, L1 can be set to open circuit and the internal load is by-passed. However, the current is still fed through a shunt resistor Rs at 340 so the load current can be measured through the voltage at Iₛₑₙₛₑ 344. Voltage may be measured at Vₛₑₙₛₑ 346. The internal load or the external load may be used and may be switched between in various embodiments. This allows use of the same fuel cell tester design to test a fuel cell, a fuel cell system (for example, a fuel cell and a fuel cartridge integrated together), or an integrated fuel cell powered portable electronic device. In one embodiment, the fuel cell tester may be integrated into a single, portable, test unit that is capable of testing small fuel cells. In a further embodiment, data acquisition capabilities and the load may be combined in one box, that may be low power, portable, and embedded or integrated. The term “portable” is used to describe devices that may be easily moved or carried by hand. When used in the context of a portable electronic device, it is used to describe hand held portable devices such as cellular phones, satellite phones, digital cameras, PDAs, ultra mobile personal computers (UMPC), laptop computers, computer accessories, personal audio or video players, and combinations thereof, and the myriad of other consumer, business and technical devices that may be carried by a person. When used in the context of a power source tester, it describes a tester that may be relatively small or compact, and can be easily transported from one location to another or easily carried by hand or the like.

The microprocessor 330 is powered by an external positive 350 and negative 355 connection or by a battery. Each of two temperature connections are fed through a linearizer 364, 365 and cold junction compensator chip and an op-amp 367, 368. Thermocouples may be located in between the cold-temperature compensation/linearizers 364, 465 and the amplification op-amps 367, 368. The microprocessor 330 is connected through a data bus 370 to a memory 375, such as an 8 Mb non-volatile flash-based memory. The microprocessor 330 is also connected through a bus 380 to an Ethernet LAN chip 385 or other network connector, including wireless transceivers.

The amount of power that can be dissipated by this embodiment of the tester 300 is determined by the FET load L1 335 and the amount of cooling it has. In one embodiment components for the tester may be selected such that the tester is adapted for testing fuel cells or other loads from 0 to approximately 10 Watts, or alternatively from 0 to approximately 20 Watts. With heat sinks and vents in the case, the tester can dissipate loads up to approximately 50 Watts, making it suitable for testing fuel cells or other power sources in the 0 to 50 Watt range. In an embodiment with active cooling such as fans, more power can be dissipated. Using such active cooling, fuel cells in the 0 to 1000 Watt range or higher may be tested.

One example of many different microprocessors or other electronics having logic capabilities that may be used is the MSC121XY5 from Texas Instruments of Houston, Tex. The CS8900A from Cirrus Logix of Austin, Tex. is one example of an Ethernet/LAN chip that can be used. An example of a FET load that can be used is the IRLZ14 from International Rectifier, of El Segundo, Calif. The non-volatile memory can be an AT45DB642 Dataflash card from Atmel of San Jose, Calif. The LT1025 from Linear Technologies of Milpitas, Calif. can be used for the linearizer and cold-junction compensator for the thermocouples. An LTKA0 also from Linear Technologies of Milpitas, Calif. can be used for the gain part of the thermocouple circuit. These examples are not meant to be limiting, as many other electronic devices which are capable of performing memory, load, temperature sensing and processing may be used.

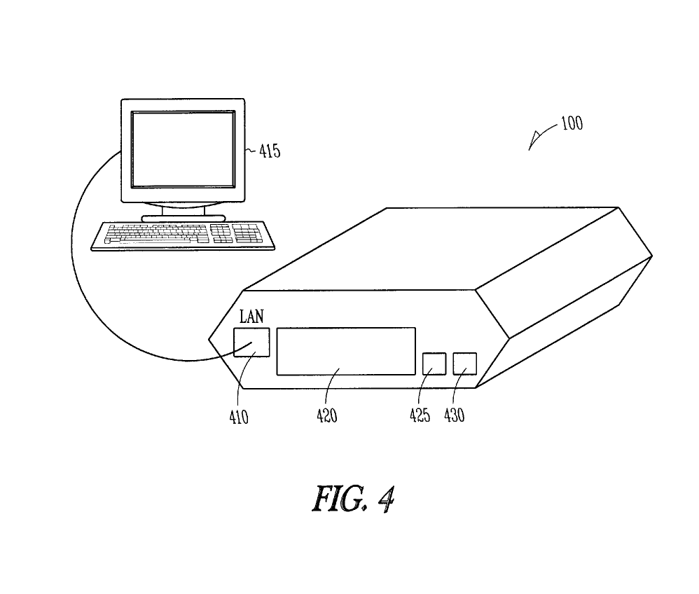

FIG. 4 shows the back face of an embodiment of the tester 100. A communications port 410 allows the device to be connected to a PC computer 415. A standard Ethernet port can be used, as can wireless connections or other hardwired connections. The computer 415 may be used to connect to the tester 100 to set up and run tests as well as to download data. While a test is running the communications cable or logical connection may be disconnected or can remain connected. Tester 100 also contains a port 420 for a battery connection, port 425 for a standard AC power connection, and a port 430 for connection to an external DC power source. Many different power sources may be used in various embodiments, and the locations of physical ports on tester 100 may be varied as desired as a function of aesthetics and/or desired function. In an embodiment, the power source may be a fuel cell system. The power supplies may be isolated with a diode. This prevents, for example, the power supply from applying a voltage across the battery. The power supplies may be isolated from circuitry by a fuse. Converters may be used to change the input voltage to an appropriate level.

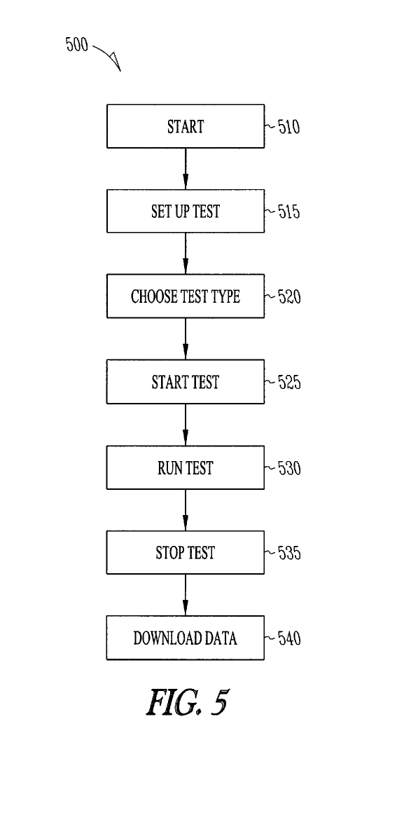

FIG. 5 shows a flow diagram 500 for an embodiment of the tester. Start 510 occurs with the tester connected to a PC, either directly or through a wired or wireless network. In one embodiment, a user of the PC may access the tester through a web browser. Other forms of communication and interaction between the user and the tester may also be used. At 515, a test is set up. Setting may include setting a time and date for the tester. The user may then choose a test type at 520. Examples of possible test types include constant voltage tests, constant current tests, constant resistance tests, constant power tests, and polarization curves. In various embodiments, multiple tests or preset combinations of tests with user-settable conditions to end each test. In one example, if a parameter such as voltage, current, power or other electrical characteristic drops below or exceeds a threshold, a next test may be started. In some embodiments, the results of one test may be used to select the next test.

In a constant voltage test, the voltage of a power source, such as a fuel cell is held approximately constant and the current permitted to change. In a constant current test, the current drawn from the power source is held approximately constant and the voltage permitted to change. A constant resistance test applies or simulates applying a load of fixed resistance to a power source and allowing both the voltage and the current to change. The constant power test involves drawing a fixed power from the power source by varying both the voltage and the current. Polarization curves determine the voltage-current characteristics of a power source by sweeping the power source through a range of voltages and currents, and measuring the results. For example, a polarization curve can be performed on a power source by varying the voltage from 0.8 volts to 0.1 volts and measuring the current.

Once the user has chosen the test type at 520 and input parameters for that test type, the user can start the test at 525. Once the test is started, the power source tester begins collecting data and storing it in memory. While the test is running at 530, the user can observe the data or samples of the data as the data is being collected. For example, the user can see a display that shows the type of test, some parameters of the test such as a set point, the voltage being measured, the current being measured, as well as the temperatures being measured through the two thermocouples. Displays may be easily created with different data displayed as desired. Alternatively, the fuel cell tester can be disconnected from the PC while the test is running. The test may be specified to run for a desired amount of time, or continuously, or periodically. A series of different tests may be specified at 520 and set to run in sequence, or even dependent upon prior test results or sensed values. The fuel cell tester will continue to operate and collect data even while it is disconnected from the PC or LAN. The LAN and PC can be reconnected at any time. With the LAN connected, the test can be stopped as indicated at 535 and the data in the memory downloaded to the PC at 540 for analysis. Alternatively, data can be downloaded at intermediate points without stopping the test. In further embodiments, data can be processed by the tester, and alarms may be generated by the tester and the user alerted to parameters outside of specified ranges or thresholds. Results of tester data processing may also be downloaded. This can be useful with battery powered testers, where one may desire to conserve power by limiting wireless transmissions to results.

In one embodiment, the tester is connected to the PC through a LAN cable. The user interacts with the tester through a web browser on a PC or a command line prompt from the PC. Minimal or no custom software may be required on the PC to interface with the fuel cell tester, so users can access the fuel cell tester through any PC connected to the fuel cell tester through a standard network. In another embodiment, the fuel cell tester can be accessed through a wireless network, or remotely through a wireless network and modem.

Various embodiments of the tester may be quite simple and low cost. The tester may be run without a computer. A computer may be used to set up the test and start the test. Once the test has started the computer can be disconnected and the test can continue indefinitely. This is particularly suitable for doing lifetime tests of fuel cells and fuel cell systems. Minimal or no custom client software need be required on the PC to run the test or download information or data from the test. Standard communications and network interface software may be used, such as a web browser, command line prompts, tftp client software for downloading files, etc.

As long as the tester has connection to the internet or other network, either through a wire or through a wireless connection, it can be accessed by any computer anywhere with a web browser. The non-volatile memory in the tester can retain its data even if the power is disrupted. Any computer or device such as a PDA with an Ethernet connection and a web browser can be used to set up tests, run tests, and download data.

The tester may be portable and can be used in the field. The tester can be powered in multiple ways, including the use of a 9-volt battery. The external load connection allows for testing of a power source such as a fuel cell with an external load such as an LED light. The tester can still log desired voltage, current, power, temperature data, gas flow rate data, humidity data, pressure data, radiation data, light data or data representative of other phenomena that can be sensed and converted to an electrical or optical signal. The tester is not limited to being used with a fuel cell or other such power source. It can be used to do short or long tests of any device that requires voltage, current, power, or temperature signals to be read and measured.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A power source tester comprising:
a processor;
an internal variable load controlled by the processor;
a network communication port coupled to the processor; and
a pair of inputs coupled to the processor for coupling to a power source to be tested under control of the processor.

2. The power source tester of claim 1 and further comprising a memory storing multiple different power test programs for execution by the processor.

3. The power source tester of claim 1 wherein the processor is a microprocessor or ASIC.

4. The power source tester of claim 1 wherein the processor executes power source tests, and logs data from such tests.

5. The power source tester of claim 4 wherein the processor sends logged data via the network communications port to a remote computer.

6. The power source tester of claim 5 wherein the logged data is sent via the Internet to the remote computer.

7. The power source tester of claim 1 wherein the processor receives commands from a remote computer via a network through the network communication port.

8. The power source tester of claim 7 wherein the tester is configured to allow the remote computer to access the processor via the Internet for setting up the processor, selecting tests, and collecting logged data from the tests.

9. The power source tester of claim 1 and further comprising a temperature port for receiving temperature information related to the power source to be tested and a port for receiving electrical signals representative of temperature, gas flow rate, humidity, pressure, radiation, or light.

10. The power source tester of claim 9 wherein the power source tester is programmed to test fuel cells.

11. The power source tester of claim 1 wherein the variable load is FET based.

12. The power source tester of claim 1 and further comprising:
a port for connection to an external load;
circuitry to allow bypassing of the internal variable load while measuring current.

13. The power source tester of claim 1 and further comprising:
a current sense; and
a voltage sense.

14. The power source tester of claim 13 and further comprising a memory for logging data representative of at least one of current and voltage.

15. The power source tester of claim 1 adapted to test power sources of less than approximately 10 Watts.

16. The power source tester of claim 1 adapted to test power sources of less than approximately 20 Watts.

17. The power source tester of claim 1 wherein the tester is portable.

18. A power source tester comprising:
a processor;
a memory having code for execution of multiple power source tests;
an internal variable load controlled by the processor;
a network communication port coupled to the processor; and
a pair of inputs coupled to the processor for coupling to a power source to be tested under control of the processor, wherein the processor is controllable via the network communication port to run selected power source tests and log data in the memory representative of such tests.

19. The power source tester of claim 18 and further comprising means for logging temperature.

20. The power source tester of claim 19 wherein the means for measuring temperature comprises a cold-junction compensation circuit and a linearizer to modify the signal from a thermocouple and feed it into the microprocessor.

21. The power source tester of claim 18 wherein the processor is programmed to communicate via the network communication port and a remote computer web browser with a user of the remote computer.

22. The power source tester of claim 18 adapted to test power sources of less than approximately 10 Watts.

23. The power source tester of claim 18 adapted to test power sources of less than approximately 20 Watts.

24. The power source tester of claim 18 wherein the tester is portable.

25. A method of testing a power source, the method executed by a power source tester comprising:
receiving remote commands via a network interface to select one or more tests to be run by the tester;
starting the selected one or more tests;
collecting and logging data during the one or more tests; and
sending the data via the network interface to a remote computer.

26. The method of claim 25 wherein the network interface is coupled to the Internet, and wherein commands are received from a web based browser on the remote computer.
